(19) United States
(12) Patent Application Publication
(10) Pub. No.: US 2005/0224714 A1
(43) Pub. Date: Oct. 13, 2005

(54) Ultra low-cost uncooled infrared detector arrays in CMOS

(76) Inventors: Tayfun Akin, Karakusunlar (TR); Selim Eminoglu, Umitkoy (TR); M. Yusuf Tanrikulu, Icel (TR)

Correspondence Address: SAWYER LAW GROUP LLP, P O BOX 51418, PALO ALTO, CA, 94303, US

(21) Appl. No.: 11/100,037

(22) Filed: Apr. 6, 2005

Related U.S. Application Data
(60) Provisional application No. 60/560,538, filed on Apr. 8, 2004.

(51) Int. Cl. H01L 25/00

(52) U.S. Cl. 250/332

(57) ABSTRACT

Micromachined, CMOS p⁺-active/n-well diodes are used as infrared sensing elements in uncooled Focal Plane Arrays (FPA). The FPAs are fabricated using a standard CMOS process followed by post-CMOS bulk-micromachining steps without any critical lithography or complicated deposition processes. Micromachining steps include Reactive Ion Etching (RIE) to reach the bulk silicon and anisotropic silicon wet etching together with electrochemical etch-stop technique to obtain thermally isolated p⁺-active/n-well diodes. The FPAs are monolithically integrated with their readout circuit since they are fabricated in any standard CMOS technology.

### FIELD OF THE INVENTION

The present invention relates to uncooled infrared detector arrays in CMOS. More specifically, this invention relates to suspended and thermally isolated CMOS p⁺-active/n-well diodes used as infrared sensing elements in uncooled infrared detector arrays. The elements are manufactured using silicon micro-machining of CMOS processed chips/wafers with Micro Electro Mechanical Systems (MEMS) technology.

### BACKGROUND OF THE INVENTION

Uncooled infrared detectors have recently gained wide attention for infrared imaging applications, due to their advantages such as low cost, low weight, low power, wide spectral response, and long term operation compared to those of photon detectors. Uncooled technology has great potential for use in various civilian applications, like driver's night vision enhancement, security cameras, heat analysis, mine detection, and fire detection. Worldwide effort is still continuing to implement very large format arrays at low cost.

Compatibility of detectors with CMOS technology, and therefore, monolithic CMOS integration is one of the pre-conditions for achieving low-cost detectors. With CMOS compatible detector technology, readout electronics can be monolithically integrated within the CMOS process. Another advantage is that additional processor electronics for noise reduction and signal processing can also be integrated effectively, reducing the cost further still for the end products.

The technique of implementing microbolometers using surface micromachined bridges on CMOS wafers for making uncooled infrared imagers is widely known to those who are experienced in the art of infrared sensor technology [(1) R. A. Wood, “Uncooled Thermal Imaging with Monolithic Silicon Focal Arrays,” Infrared Technology XIX, Proc. of SPIE vol. 2020, pp. 322-329, 1993; (2) C. Vedel, J. Martin, J. Ouvrier Buffet, J. Tissot, M. Vilain, and J. Yon, “Amorphous Silicon Based Uncooled Microbolometer IRFPA,” Proc. of SPIE Vol. 2698, pp. 276, 284, 1999; (3) S. Sedky, P. Fiorini, K. Baert, L. Hermans, and R. Mertens, “Characterization and Optimization of Infrared Poly Si Ge Bolometers,” IEEE Transactions on Electron Devices 46, pp. 675-682, 1999; (4) H. Wada, T. Sone, H. Hata, Y. Nakaki, 0. Kaneda, Y. Ohta, M. Ueno, and M. Kimata, “YBaCuO Uncooled Microbolometer IRFPA,” Sensors and Materials, vol. 12, no. 5, pp. 315-325, 2000; (5) J. S. Shie, Y. M. Chen, M. O. Yang, and B. C. S. Chou, “Characterisation and Modeling of Metal-Film Microbolometer,” J. of Microelectromechanical Systems Vol. 5, No. 4, pp. 298-306, December 1996]. Incident infrared radiation on the material constructing the thermally isolated suspended bridge structure causes changes in its temperature. This temperature change causes a change in the electrical properties of the sensing element, which is readout using proper electronic circuitry. In surface micromachined microbolometers, the sensing element is selected as a resistor, where the resistor is implemented using materials that have high Temperature Coefficient of Resistance (TCR) to achieve high performance.

There are efforts to implement microbolometers using many different high TCR materials, such as Vanadium Oxide (VOₓ) (R. A. Wood, “Uncooled Thermal Imaging with Monolithic Silicon Focal Arrays,” Infrared Technology XIX, Proc. of SPIE Vol. 2020, pp. 322-329, 1993), amorphous Silicon (a-Si) (C. Vedel, J. Martin, J. Ouvrier Buffet, J. Tissot, M. Vilain, and J. Yon, “Amorphous Silicon Based Uncooled Microbolometer IRFPA,” Proc. of SPIE Vol. 3698, pp. 276-283, 1999), polycrystalline silicon-germanium (poly SiGe) (S. Sedky, P. Fiorini, K. Baert, L. Hermans, and R. Mertens, “Characterization and Optimization of Infrared Poly SiGe Bolometers,” IEEE Transactions on Electron Devices 46, pp. 675-682, 1999), and YBaCuO (H. Wada, T. Sone, H. Hata, Y. Nakaki, O. Kaneda, Y. Ohta, M. Ueno, and M. Kimata, “YBaCuO Uncooled Microbolometer IRFPA,” Sensors and Materials, vol. 12, no. 5, pp. 315-325, 2000), although there are also microbolometers implemented with low TCR materials such as metals (J. S. Shie, Y. M. Chen, M. O. Yang, and B. C. S. Chou, “Characterisation and Modeling of Metal-Film Microbolometer,” J. of Microelectromechanical Systems Vol. 5, No. 4, pp. 298-306, December 1996) to eliminate the drawbacks of high TCR materials.

The main drawback of VOₓ (R. A. Wood, “Uncooled Thermal Imaging with Monolithic Silicon Focal Arrays,” Infrared Technology XIX, Proc. of SPIE Vol. 2020, pp. 322-329, 1993) is that it is not compatible with CMOS processes and it exhibits large low frequency noise due to its non-crystalline structure, limiting its performance. CMOS integration is achieved by having a number of deposition, lithography, and etching steps after the CMOS process, increasing the cost of fabrication and reducing yield. These factors limit the use of infrared detectors with VOₓ in ultra low-cost applications. Also, VOₓ contaminates the CMOS line; therefore, dedicated process equipments and a dedicated cleanroom environment are necessary for the deposition of VOₓ and any further process step following this deposition step.

Poly SiGe (S. Sedky, P. Fiorini, K. Baert, L. Hermans, and R. Mertens, “Characterization and Optimization of Infrared Poly SiGe Bolometers,” IEEE Transactions on Electron Devices 46, pp. 675-682, 1999) and a-Si (C. Vedel, J. Martin, J. Ouvrier Buffet, J. Tissot, M. Vilain, and J. Yon, “Amorphous Silicon Based Uncooled Microbolometer IRFPA,” Proc. of SPIE Vol. 3698, pp. 276-283, 1999) are CMOS line compatible high TCR materials, i.e., they do not contaminate the CMOS lines; however, they require high temperature annealing to achieve stability of microstructures, making the monolithic CMOS integration difficult. In addition, both a-Si and poly SiGe have high low frequency noise due to their non-crystalline structures, as VOₓ. Futhermore, CMOS integration is also achieved by having a number of depositions, lithography, and etching steps after the CMOS process, increasing the cost of detectors.

Deposition of YBaCuO is performed at room temperature; however, fabrication of detectors using YBaCuO (H. Wada, T. Sone, H. Hata, Y. Nakaki, 0. Kaneda, Y. Ohta, M. Ueno, and M. Kimata, “YBaCuO Uncooled Microbolometer IRFPA,” Sensors and Materials, vol. 12, no. 5, pp. 315-325, 2000) still require complicated post-CMOS surface micromachining processes as the above materials.

On the other hand, metals are both CMOS compatible, and their fabrication does not require any high temperature process steps (J. S. Shie, Y. M. Chen, M. O. Yang, and B. C. S. Chou, “Characterisation and Modeling of Metal-Film Microbolometer,” J. of Microelectromechanical Systems Vol. 5, No. 4, pp. 298-306, December 1996). However, metal microbolometers not only require deposition and lithography steps after CMOS, but also have low performance due to the low TCR value of metal films.

T. Ishikawa et al reports in “Performance of 320×240 Uncooled IRFPA with SOI Diode Detectors (T. Ishikawa, M. Ueno, Y. Nakaki, K. Endo, Y. Ohta, J. Nakanishi, Y. Kosasayama, H. Yagi, T. Sone, and M. Kimata, “Performance of 320×240 Uncooled IRFPA with SOI Diode Detectors,” Proc. of SPIE Vol. 4130, pp. 1-8, 2000), a new approach, whereby silicon p-n diodes are used as a temperature sensitive element in microbolometer arrays. Arrays comprising 320×240 FPA pixels are based on suspended multiple series diodes with 40 μm×40 μm pixel sizes on Silicon On Insulator (SOI) wafers. Although this approach provides very uniform arrays with very good potential for low-cost high performance uncooled detectors, its fabrication is based on a dedicated in-house SOI process. Since these detectors can not be implemented in a standard CMOS process, it would be difficult to reduce their costs down to limits that ultra low-cost applications require.

In summary, none of the previous approaches provide a good solution for ultra low-cost uncooled infrared detector arrays, as they have one or more of the following drawbacks:
(i) They use high TCR materials that are not CMOS line compatible, requiring dedicated additional equipment;
(ii) They use high TCR materials that are not CMOS process compatible, making the integration with CMOS circuit difficult;
(iii) They require complicated post-CMOS processes including a number of critical lithography, deposition, and etching steps;
(iv) They require dedicated in house CMOS processes with non standard CMOS process steps.

In U.S. Pat. No. 5,450,053, dated 12 Sep. 1995, assigned to Honeywell Inc., R. A. Wood describes a microbolometer infrared radiation sensor by creating thermally isolated microbridges on CMOS wafers with surface micromachining while using a detector material, VO₂ (Vanadium Oxide) having a high thermal coefficient of resistance to increase sensitivity of apparatus. Although the approach can be used to create large format infrared FPAs, the use of surface micromachining and VOₓ material does not allow implementing ultra low-cost infrared FPAs as explained above in opposition to public disclosure document (R. A. Wood, “Uncooled Thermal Imaging with Monolithic Silicon Focal Arrays,” Infrared Technology XIX, Proc. of SPIE Vol. 2020, pp. 322-329, 1993).

In U.S. Pat. No. 5,600,174, dated Feb. 4, 1997, titled “Suspended Single Crystal Silicon Structures and Method of Making Same,” Reay et al describe a method of constructing temperature-sensitive transducers and other circuitry that are manufactured by an electrochemical post-processing etch on an integrated circuit fabricated using a conventional CMOS process. The technique suggests selective etching of exposed front-side regions of a p-type silicon substrate to leave n-type wells suspended from oxide beams. This technique can be used to implement diodes in suspended n-well structures from standard CMOS, and it is claimed that a temperature sensor can be implemented with this diode. However, Reay et al fail to realize that the diodes cannot be used to implement high performance uncooled infrared focal plane arrays. First of all, the fill factors of the diodes will not be high enough with the suggested opening formation to achieve exposed silicon substrate, where it is suggested that the regions of exposed silicon substrate are obtained by creating a stack of several oxide holes. With the current sub-micron CMOS processes, the suggested method of achieving exposed silicon substrate does not work, as the dielectric and other layer thicknesses are large. In addition, Reay suggests in U.S. Pat. No. 5,600,174 that the manufacture of temperature-sensitive transducers through a technique consisting of an electrochemical post-processing etch on an Integrated Circuit (IC) with exposed metallization fabricated using a CMOS process, where TetraMethyl Ammonium Hydroxide (TMAH), or another anisotropic etchant with similar characteristics, is used to selectively etch exposed front-side regions of a p-type silicon substrate. If the metallization layers of a CMOS process are exposed to TMAH, then a number of different additives are required to prevent the etching of these metal layers. However, when these additives are added, then the undercut of the opening areas is going to increase, and therefore, the walls between the pixels will be etched, causing pixel cross-talk. A high degree of pixel cross-talk prevents making good quality Focal Plane Arrays (FPA). To keep the walls intact after etching, the widths of the walls can be increased. This process, however, will reduce the fill factor of the pixel in the FPA, reducing the efficiency. In summary, the suggested methods in U.S. Pat. No. 5,600,174 by Reay et al will not achieve the performance necessary for creation of large format low-cost uncooled infrared detector focal plane arrays.

Fedder at al (G. K. Fedder, S. Santhanam, M. L. Reed, S. C. Eagle, D. F. Guillou, M. S.-C. Lu, and L. R. Carley, “Laminated High-Aspect Ratio Microstructures in a Conventional CMOS Process,” The Ninth Annual International International Workshop on Micro Electro Mechanical Systems, IEEE, pp. 13-18, February 1996), reports in “Laminated High-Aspect Ratio Microstructures in a Conventional CMOS Process,” a method of making electrostatically actuated microstructures using a conventional CMOS process followed by a sequence of maskless dry-etching steps. This approach allows reaching the exposed silicon, on silicon substrate with an accuracy of the CMOS process without needing a critical masking step. In this work, the silicon substrate is etched with an isotropic wet etch to release the microstructures for electrostatic actuation. However the use of isotropic wet etching after the dry etching cannot be used to implement diode type uncooled infrared detector FPAs. Isotropic wet etching cannot be used with electrochemical etch-stop to achieve suspended diode structures. Furthermore, isotropic wet etching removes the sidewalls, increasing the thermal cross-talk between the pixels of the FPA and decreasing the mechanical strength of the FPA. If the width of the sidewalls are made large to prevent their entire etching, then the pixel fill factor will reduce and pixel size will increase, both of which are not desired to achieve low-cost, high performance uncooled infrared detector FPAs. There are a number of follow up papers, dated after public domain reference (G. K. Fedder, S. Santhanam, M. L. Reed, S. C. Eagle, D. F. Guillou, M. S.-C. Lu, and L. R. Carley, “Laminated High-Aspect Ratio Microstructures in a Conventional CMOS Process,” The Ninth Annual International International Workshop on Micro Electro Mechanical Systems, IEEE, pp. 13-18, February 1996), by the same individuals and the other individuals in Fedder's group, on the topic of sensors, fabricated based on maskless dry-etching steps, but none of the reported work can be used to implement diode type uncooled infrared detector FPAs presented in the present invention.

### SUMMARY OF THE INVENTION

The present invention describes methods and systems for implementing ultra low-cost infrared detector arrays together with their readout circuitry fully on standard CMOS, using simple post-CMOS etching steps where neither critical lithography nor detector material deposition steps are needed.

A post-CMOS processing approach on wafers fabricated using a CMOS process allows the fabrication of a low-cost small pixel size novel detector structure. The detectors in pixels are implemented with p⁺-active/n-well diodes, which are suspended and thermally isolated from the bulk silicon substrate by etching the silicon underneath the diode using an anisotropic etchant. In order to let the etchant reach the silicon layer to be etched, an RIE step is used to etch the dielectric layers in the CMOS process. Selectively placed CMOS metal layers define the final pixel structure without any lithography, substantially reducing the cost of the fabrication process. The etching of the diode is prevented with electrochemical etch-stop technique. This novel approach is used for first time to implement suspended diode FPAs with standard CMOS technology for uncooled infrared imaging. The detectors have an oxide-metal-oxide sandwich layer on top as the infrared absorbing layer. Other absorber layers can be deposited if higher infrared power absorption is needed. The two support arms allow for the suspension of the diode in each pixel and also carry the electrical signals with an interconnect layer in CMOS. The interconnect layer is selected as a polysilicon layer to increase the thermal isolation between the bulk silicon substrate and the diode in the pixel. The structure to implement the pixel and the post-CMOS process to create the suspended diode arrays are carefully selected to achieve a high performance and low-cost uncooled infrared focal plane arrays. The layout of the pixel and the process steps are very important in order to have small pixel size with high fill factors, good thermal isolation between the suspended diodes and the bulk substrate, low thermal time constant, low thermal mass of the diode structure, high mechanical strength of the supporting arms, and thermal isolation of the pixels from each other to reduce the thermal cross talk.

With the approach in accordance with the present invention, it is possible to implement large format FPAs such as 128×128 pixels or larger formats with small pixel sizes, such as 40 μm×40 μm with a fill factor of 44%. It will be apparent to those skilled in the art that many different pixel and array sizes can be built using the same sensor structure by slightly modifying the process. The present invention is not in any way restricted by any pixel size or fill factor. The use of diodes as the sensing elements allows achieving very low noise when they are biased at low current. Low biasing current also allows achieving small self heating of the suspended pixel. The selection of a proper value for biasing current for achieving high FPA performance depends on the pixel size, diode area, and the resistance on the interconnect layer. As the bias current increases, the small signal resistance of the diode decreases, decreasing its shot noise current. However, as the current increases, the low frequency noise component in the polysilicon arms increases and there is a reduction in diode temperature coefficient (TC). So there is an optimum operating point for the diode biasing. For the specific FPA mentioned above, the optimum point is around 20 μA, and depending on the CMOS process and diode structure, it can be anywhere between 5 μA and 50 μA.

### BRIEF DESCRIPTION OF THE DRAWINGS

FIG. 1 is a perspective view of a general p⁺-active/n-well diode microbolometer that can be obtained in a standard n-well CMOS process.

FIG. 2 shows a single pixel p⁺-active/n-well diode microbolometer having two-folded support arms, (a) top view, (b) cross section.

FIG. 3 is a process flowchart of the novel detectors.

FIG. 4A shows a post-CMOS fabrication steps and the cross-section of the pixel structure after a 3-metal CMOS process.

FIG. 4B shows a post-CMOS fabrication steps and the cross-section of the pixel structure after dry-etch.

FIG. 4C shows a post-CMOS fabrication steps and the cross-section of the pixel structure after anisotropic silicon etch processes.

FIG. 5 is a schematic view of the electronic pixel connection inside the array, including the circuitry used for post processing in a M×N focal plane array.

FIG. 6A shows post-CMOS fabrication steps and the cross-section of the pixel structure after a 2-metal CMOS process.

FIG. 6B shows post-CMOS fabrication steps and the cross-section of the pixel structure after dry-etch.

FIG. 6C shows post-CMOS fabrication steps and the cross-section of the pixel structure after anisotropic silicon etch processes.

### DETAILED DESCRIPTION

The present invention relates to uncooled infrared detector arrays in CMOS. The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

In accordance with the present invention, a microbolometer infrared sensor pixel design and sensor array design compatible with CMOS process is described. The pixel design and the resulting sensor array does not require any critical post-CMOS lithography and complex deposition processes that increase fabrication costs and reduce yield. The invention makes it possible by design and by cascading suitable processes correctly to fabricate large ultra low-cost infrared detector arrays for infrared imaging.

In the present invention, implementation of the ultra low-cost infrared sensor array is not limited to CMOS processes. The focal plane array (FPA) can also be implemented with various other standard IC processes, such as BiCMOS or SOI CMOS, etc. Additionally, the number of metal and polysilicon layers that are used in the processes may be different. Those who are skilled in the art will appreciate that the number of metal and polysilicon layers in different standard processes may vary and these layers can be used in a number of different ways to implement very different pixel and FPA structures by using the core of the invention.

A. Structure of Detector Pixels

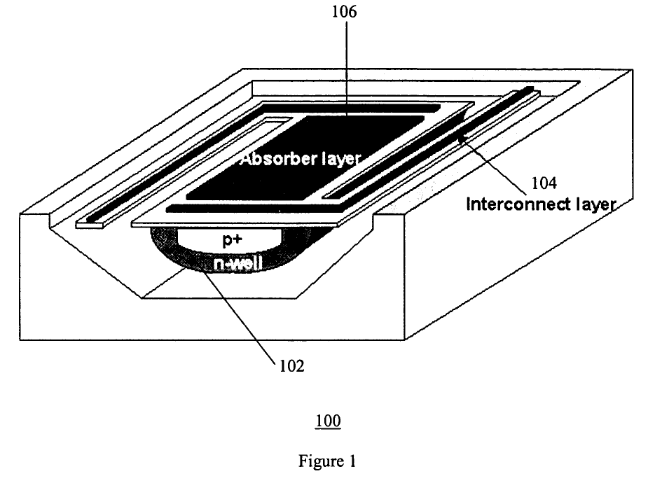

FIG. 1 shows a perspective view of a general single pixel p⁺-active/n-well diode microbolometer 100 that can be obtained in a standard n-well CMOS process. Infrared radiation heats the absorbing layer 106 on the thermally isolated n-well 102, increasing its temperature, which in turn results in a change in the diode voltage related to its temperature coefficient. This change is monitored with proper on-chip readout electronics.

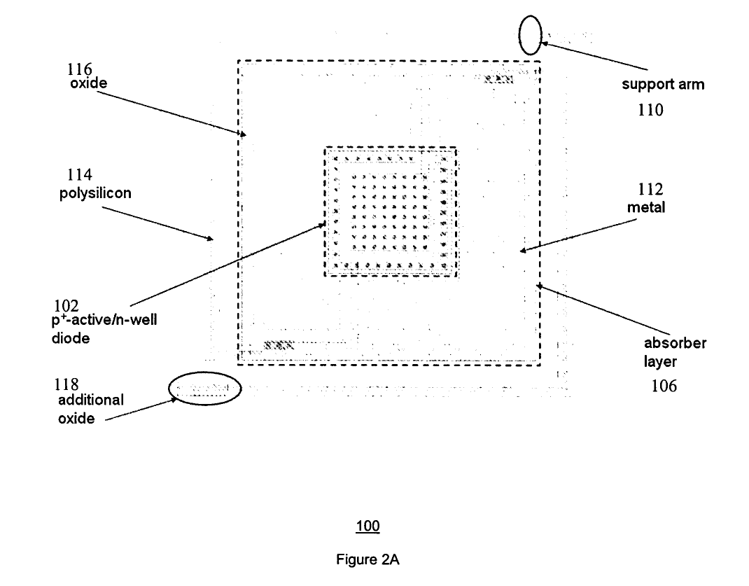

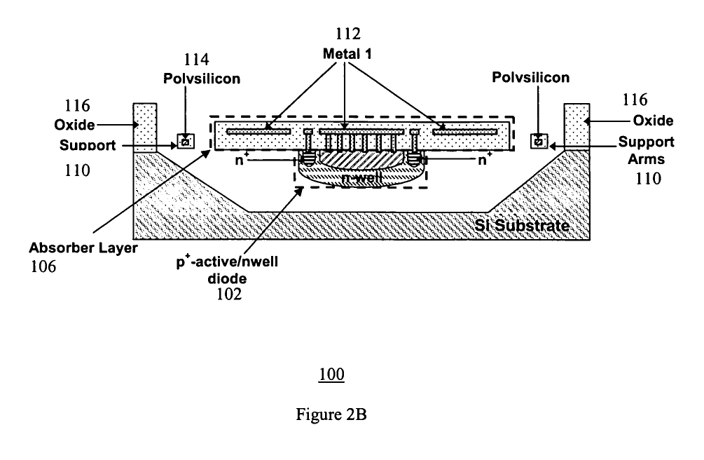

FIG. 2A shows the top view of a single pixel p⁺-active/n-well diode microbolometer 100 having two-folded support arms 110. The pixel includes the temperature sensitive p⁺-active/n-well diode 102, IR absorbing layer 106, two support arms 110 which carry the body of the pixel 100 as well as the electrical signal, and an additional oxide layer 118 on the support arms 110.

The p⁺-active/n-well diode 102 is formed by making p⁺ diffusion into the n-well layer of the CMOS process. The diode 102 is made small and at the middle of the pixel 100 in order to decrease the thermal capacitance of the pixel and to make the post-CMOS anisotropic silicon etching easier. It will be clear to those who are skilled in the art that the diode 102 may be placed in a different place under the absorber layer 106 and may be made larger in order to satisfy different efficiency, pixel size, and mechanical strength requirements.

The two support arms 10 are interconnects of the body to the substrate. These support arms 110 are made of oxide and an interconnect layer which can be metal or polysilicon in a CMOS process. As the interconnect layer polysilicon 114 is preferred because of its stiffness and lower thermal conductance. The pixel 100 in FIG. 2A has two-folded support arms 110 to increase the length of the arms and consequently to decrease the thermal conductance of the pixel 100. Clearly the shape, length, and the number of the support arms 110 can be changed depending on the performance requirements. The thickness of the support arms 110 is defined by the selection of the masking metal layer 112. A thinner support arm is preferred when the thermal conductance of the pixel 100 is considered. In this case, the first metal of the CMOS process is used as the masking layer in the support arms 110. This is the case shown in FIGS. 2A and 2B, FIGS. 4A, 4B and 4C, and FIGS. 6A, 6B, and 6C. If thicker support arms 10 are required for mechanical strength, then, the second metal of the CMOS process can be used as the masking layer in the support arms. It should be noted that any metal layer in the CMOS process can be used for masking of the support arms 110. Also, various combinations of metal layers can be used in the support arms 110 to improve the strength of the support arms 110. For example, FIG. 2A shows the additional oxide layers 118 on the support arms 110 where they are connected to the substrate to increase the strength of the arms 110 by decreasing a possible stress on the arms of the pixel 100. Similar additional oxide layers 118 can be placed on the support arms 110 where they are connected to the suspended diode region.

FIG. 2B shows the cross section of the pixel 100 after the post-CMOS fabrication is completed. The bulk silicon underneath the pixel 100 is etched away to increase the thermal isolation of the pixel 100. The suspended structure is carried by the support arms 110. The oxide 116 on the both sides of the pixel 100 is used for isolation of the routing lines when an imaging array is formed using this pixel.

The IR absorbing layer 106 can be formed using the dielectric layers of the CMOS process, as these layers can absorb infrared radiation. The thickness and the shape of the absorber layer 106 is defined with the proper layout of the pixel 100 and selection of the metal layers that are used for the masking layers. The area of the absorber layer 106 defines the fill factor of the pixel for a fixed pixel size, and therefore, it is better to define the absorber area as large as possible. The increase in the thickness of the absorber layer 106 increases the absorption coefficient; however, it also increases the thermal mass and therefore thermal time constant of the pixel 100. Having a metal layer under the dielectric absorber layer 106 acts as a reflector for the infrared radiation, and this kind of structure also increases the absorption coefficient. It is important to note that, in this case, the metal layer also increases the thermal mass and therefore the thermal time constant of the pixel 100. Those who are skilled in the art know that the thickness of the dielectric and metal layers might be different on different standard CMOS processes, and therefore, many different combinations of the pixel can be created to optimize the overall pixel performance for infrared detection.

B. Fabrication

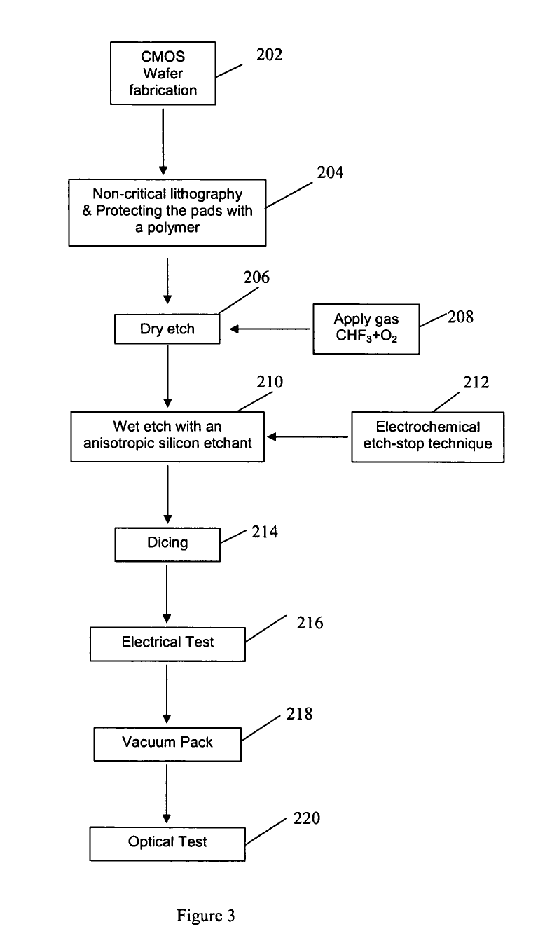

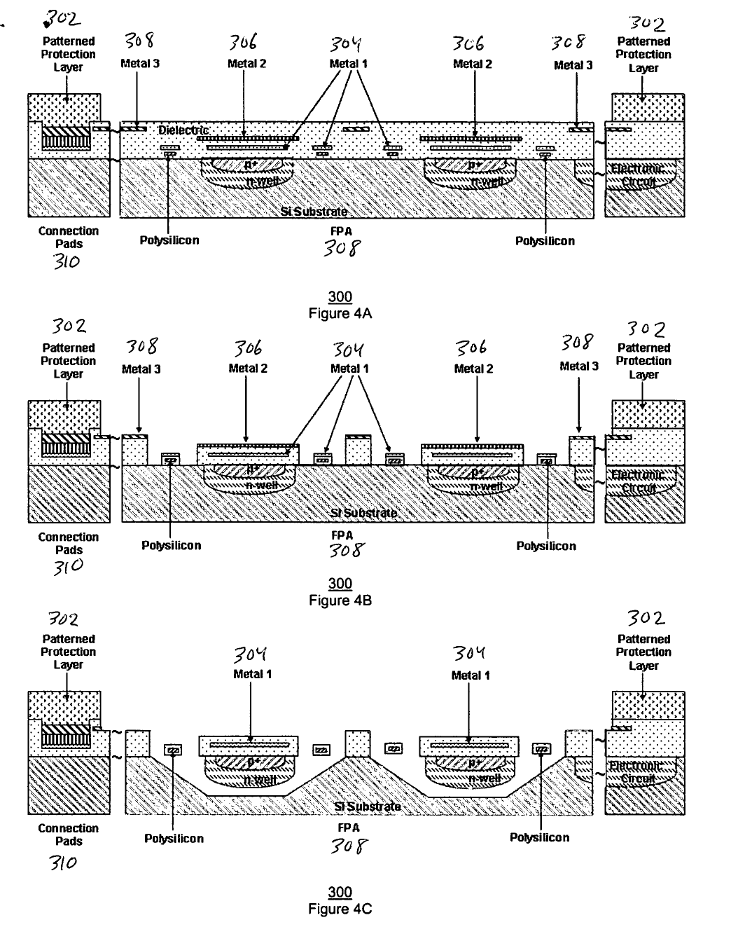

FIG. 3 shows the fabrication process flowchart of the novel detectors and FPAs. FIGS. 4A, 4B and 4C show Post-CMOS fabrication steps and the cross-section of the pixel structure after a 3-metal CMOS process (FIG. 4A); after dry-etch (FIG. 4B), and anisotropic silicon etch processes (FIG. 4C). After the chips/wafers arrive from the CMOS process, the connection pads and electronic circuitry are covered with a protection layer 302 which might be achieved with a combination of various metal and polymer layers (such as aluminium, Benzo-CycloButene (BCB), photoresist, etc.). The protection layer 302 is used to prevent the etching of the pads and the electronics circuitry during the RIE and anisotropic silicon etching. The protection layer 302 is patterned with non-critical lithography and etching steps because it is sufficient to cover the areas other than the focal plane array region for the RIE step. The protection layer 302 is also used to protect the etching of the pads 310 during the wet etching of the bulk silicon in an anisotropic silicon etchant such as TMAH or a similar etchant. This allows the easier optimization of the anisotropic silicon etchant to achieve high fill factor structures for high infrared detection performance.

FIG. 4B shows the Dry-etch step, also referred to as the RIE step, which is one of the major steps in the fabrication of these novel detectors. The RIE step is used to etch the oxide layers in the openings of the detectors to reach the bulk silicon which should be exposed to the etchant that will be used in the next step. During the RIE step, the metal layers 304, 306 and 308 of the CMOS process are used as the protection mask to prevent the etching of the oxide on the support arms and the absorber layer. During the dry-etch process, a mixture of CHF₃ and O₂ gases are administrated into the chamber to etch the dielectrics of the CMOS process while creating vertical side walls as much as possible, but not to etch the metals of the CMOS process, since they are used as masking layer. Since the metal layers 304, 306 and 308 of the CMOS process are used as the protection mask, there is no need for critical lithography for the masking of the support arms and the body of the pixel. Critical lithography is defined by the accuracy required in the process. Any accuracy finer than 5 μm is critical and is one of the very important factors in increasing the cost of fabrication. The most important advantage of this method is to define the mechanical structure of the pixels with the lithography accuracy of the CMOS process used, without a further need for any critical post-CMOS lithography. Defining the mechanical structure of the pixel precisely allows implementing small pixel size infrared detectors with high fill factors which are necessary for fabrication of high performance large format uncooled infrared focal plane arrays.

After the RIE step, the metal layers that are used for the RIE mask are removed in a selective wet-etchant as shown in FIG. 4C. Then, the bulk silicon underneath the detector pixel is etched away in order to create a thermally isolated suspended structure, which is necessary to increase responsivity of the detector. This thermally isolated suspended structure is obtained by front-end bulk etching of fabricated CMOS dies/wafers in an anisotropic silicon wet etchant, where the electrochemical etch-stop technique is used to prevent the etching of the n-well.

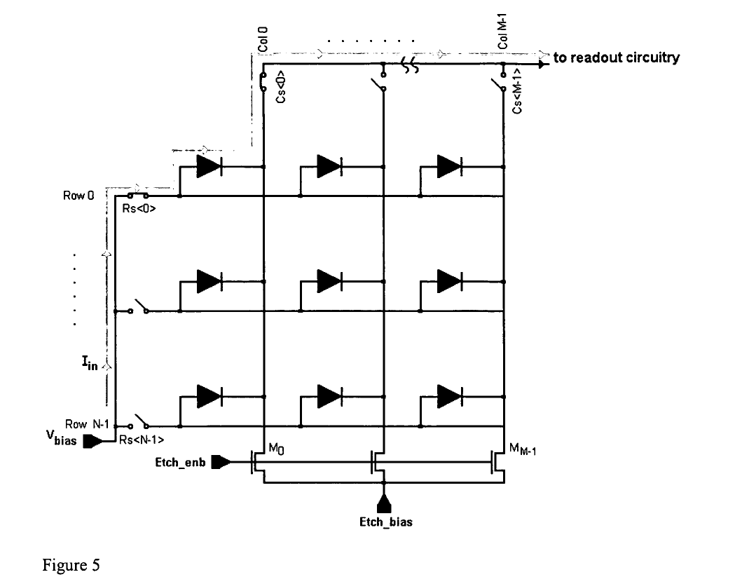

During this etching, an etch-stop voltage is applied to all the n-wells in the M×N array, where M and N are the number of columns and rows in an FPA, respectively. FIG. 5 shows the schematic view of the electronic pixel connection inside the array, including the circuitry used for post processing in an FPA. On each column, n-wells are shorted using interconnect layers in the CMOS process by a specific architecture of the readout. In normal operation, columns are electrically isolated from each other; however, during the wet etch, they are shorted together using the switch transistors M₀-M_{M-1}. This way, the Etch_bias voltage of −0.5V is applied to all of the n-well in the FPA to prevent the etching of the n-well in the anisotropic etchant. Those who are skilled in the art will realize that the value of the Etch bias voltage will depend on the anisotropic etchant used and the doping characteristic of the n-well. During the anisotropic wet etching, the voltages on the p⁺ sides of the diodes are not critical, and they can be left floating or they can be connected to a certain voltage that prevents the turning on of the diodes. After the etching and during the normal operation of the FPA, proper voltages are given to Etch enb and Etch bias to keep the transistors M₀-M_{M-1} off. This way, only the n-wells on the same column are left short to each other. Access to the individual diodes in the pixels is achieved with the column select switches (Cs<0>-Cs<M-1>) and row select switches (Rs<0>-Rs<N-1>). As an example, FIG. 5 shows how to access the diode of the pixel at location <0,0>by turning on the switches Rs<0> and Cs<0>. Similarly, the other pixels are accessed. This way of connection prevents the use of any switching transistor inside the individual pixels, reducing the size and number of connections to the suspended structure. This is the first time that such a circuit is used in diode type uncooled FPAs for infrared imaging.

An important advantage of this fabrication approach is the fact that thermal isolation walls can be created between the individual pixels with the special features of the anisotropic wet etchants, preventing pixel thermal cross talk. Anisotropic etchants has low etch rates for the <111> crystallographic planes of the silicon substrates compared to <100> crystallographic planes. The smaller the value of <111> plane etch rate compared to <100> plane etch rate is better for the performance of the pixel, because the wall spacing in the layout can be made smaller. This is important to achieve high fill factor and small pixel size.

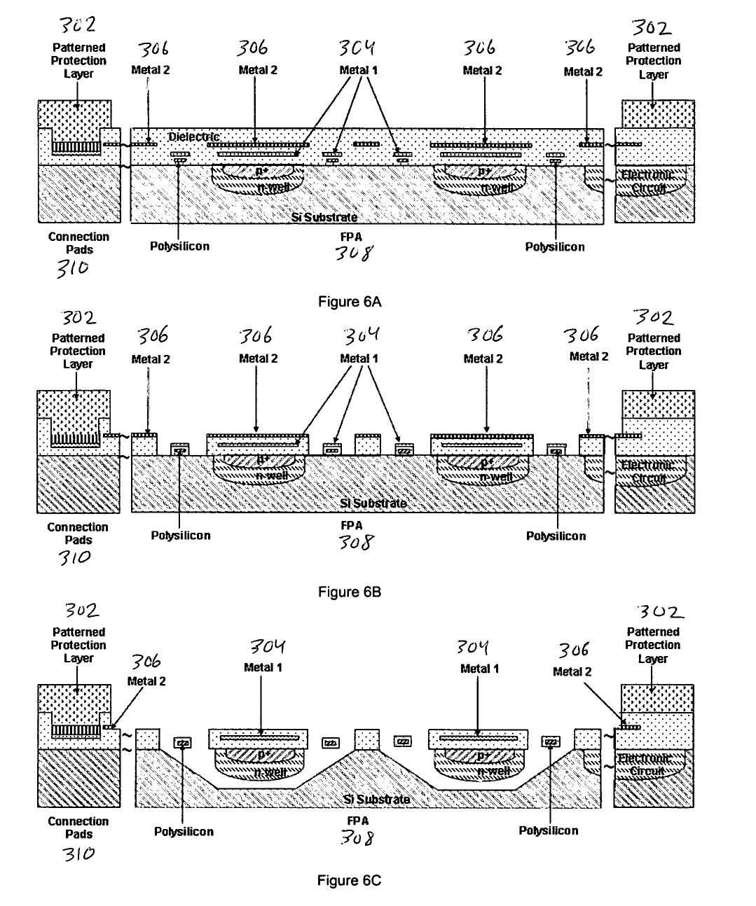

The most critical process steps in this approach is the protection of the pads and other parts of the circuit after CMOS process, and then the RIE etching of the dielectric layers to reach the silicon and definition of the pixel opening and shape in this RIE etching, and then the wet anisotropic etching to suspend the diodes, while protecting the etching of the diodes using electrochemical etch stop. After these critical steps, the wafer should be diced, tested, vacuum packaged, and optically tested as shown in FIG. 3. Those who are skilled in the art will know that the order of these final steps are not critical and can change depending on the packaging and testing strategy. For example, if wafer level vacuum packaging is used, then dicing should come after vacuum packaging. Partial electrical testing can be done on wafer level to decrease the cost. An IR window can be put to the top covering of the package in case the die is individually vacuum packaged, or the cap wafer that is used in the wafer level packaging can be coated properly to achieve IR filtering. In addition, those who are skilled in the art will appreciate that the number of metal and polysilicon layers in different CMOS processes may vary and these layers can be used in a number of different ways to implement very different pixel and FPA structures by using the core of the invention as detailed in this document. For example, FIGS. 6A, 6B and 6C show Post-CMOS fabrication steps and the cross-section of the pixel structure after a 2-metal CMOS process (FIG. 6A), after dry-etch (FIG. 6B), and anisotropic silicon etch processes (FIG. 6C). Similarly, the process described in this document can be used to implement diode type uncooled microbolometer FPAs in other CMOS processes, such as BICMOS, SOI CMOS, and SOI BICMOS processes.

This method of making an infrared detector array using a standard CMOS process has a number of advantages. First of all, it does not require any critical lithography step after the CMOS process, reducing the cost of the process. In addition, the gaps between the arms can be reduced as the CMOS technology progresses, making it possible to reduce the pixel size while increasing the fill factor. Also, there is no need for any complicated post-CMOS deposition or surface micromachined process steps. Therefore, the detector cost is virtually equal to the cost of a CMOS chip.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

1. A single pixel microbolometer comprising:
at least one suspended diode;
an infrared absorber layer; and
at least one of support arm for holding the at least one suspended diode, wherein the at least one of the support arm for carrying electrical signals to the at least one diode using an interconnect layer.

2. The single pixel microbolometer of claim 1 wherein the diode comprises a p⁺-active/n-well diode.

3. The single pixel microbolometer of claim 1 wherein the at least one support arm comprises two support arms.

4. The single pixel microbolometer of claim 1 wherein the interconnected layer can be metal or polysilicon.

5. The single pixel microbolometer of claim 1 wherein the microbolometer is implemented by using any of a standard CMOS process, BICMOS process, SOI CMOS process and SOI BICMOS process.

6. A method for providing a single pixel microbolometer comprising:
providing connection pads protected during post-CMOS processes with polymer/metal combinations without critical post-CMOS lithography, wherein critical lithography is defined as a lithography process requiring an accuracy of less than 5 μm;
dry etching using CMOS metal layers as precisely defined masks for the pixel formation; and
wet-etching using a silicon etchant for creation of a suspended diode structure.

7. The method of claim 6 wherein the wet-etching comprises bulk etching of fabricated CMOS dies/wafers using an anisotropic silicon etchant; and controlled by electrochemical etch-stop technique.

8. The method of claim 7 which includes biasing of the n-well layers of the individual diodes in a focal plane array (FPA) format with special circuitry.

9. The method of claim 6 wherein the microbolometer is implemented by using any of a standard CMOS process, BICMOS process, SOI CMOS process and SOI BICMOS process.

10. A focal plane array (FPA) comprising:
an array of single pixel microbolometers wherein each of the microbolometers comprise at least one suspended diode; an infrared absorber layer; and at least one of support arm for holding the at least one suspended diode, wherein the at least one of the support arm for carrying electrical signals to the at least one diode using polysilicon or metal as an interconnect layer.

11. The focal plane array of claim 10 wherein the array is sensitive to infrared radiation in the wavelength range of 6 μm to 18 μm.

12. The focal plane array of claim 10 wherein pixel cross-talk is prevented with silicon sidewalls between the pixels achieving array sizes from 8×8 to 1024×1024 including but not confined to non square arrays.

13. The focal plane array of claim 10 which includes:
a monolithically integrated readout circuit in standard CMOS process.

14. The focal plane array of claim 13 wherein the integrated readout circuit comprises:
row and column electronic switches allowing unique addressing of each pixel for monitoring of the diode turn on voltage in each pixel; and
a read out circuit extracting the absorbed heat information from the diode turn on voltage of each pixel.

15. The focal plane array of claim 10 wherein the microbolometer is implemented by using any of a standard CMOS process, BICMOS process, SOI CMOS process and SOI BICMOS process.

16. A method for providing a single pixel microbolometer comprising:
using the layers of CMOS process as the protection mask during post-CMOS processes;
using a post-CMS deposited polymer/metal combination as the protection of the pads and other regions that require protection during post-CMOS processes;
using Reactive Ion Etching (RIE);
etching in oxygen and flourine based gases such as CHF₃;
allowing narrow openings, resulting in high fill factor;
allowing etching of oxide layers to create openings to reach silicon; and
allowing etching of silicon to form suspended diode structures.
